(19) United States
(12) Patent Application Publication
(10) Pub. No.: US 2016/0099516 A1
(43) Pub. Date: Apr. 7, 2016

(54) ELECTRONIC DEVICES

(71) Applicant: Samsung Electronics Co., Ltd., Gyeonggi-do (KR)

(72) Inventor: Ki-Jung KIM, Gyeonggi-do (KR)

(21) Appl. No.: 14/862,440

(22) Filed: Sep. 23, 2015

(30) Foreign Application Priority Data
Oct. 2, 2014 (KR) 10-2014-0133418

(51) Int. Cl. H01R 13/62; H05K 7/14; H05K 9/00; H05K 1/18

(52) U.S. Cl. CPC H01R 13/6205; H05K 1/181; H05K 7/1427; H05K 9/0024

(57) ABSTRACT

An electronic device includes a connection unit that is electrically connected with an external connection jack utilizing a magnetic force for a non-insertive electrical connection. According to an embodiment, the electronic device may include an electronic device main body; a printed circuit board that is provided in the electronic device main body and that has a connection unit and a plurality of electronic components mounted thereon; and a magnetic connection device unit that is provided in the electronic device main body and that electrically connects the connection unit with an external connection jack by a magnetic force.

### CLAIM OF PRIORITY

This application claims the priority under 35 U.S.C. §119(a) from Korean Application Serial No. 10-2014-0133418, which was filed in the Korean Intellectual Property Office on Oct. 2, 2014, the entire content of which is hereby incorporated by reference in its entirety.

### BACKGROUND

1. Field of the Disclosure

The present disclosure relates to an electronic device including a connection unit.

2. Description of the Related Art

In general, portable electronic devices are carried by a user in order to access a communication function such as a voice call or a short message service, a multimedia function such as playing music and/or movies, and an entertainment function such as games.

Such portable electronic devices have various types according to specialized functions and portability. For example, the portable electronic devices may be divided into a bar type, a folder type, or a sliding type according to appearance. Recently, with the trend of strengthening multimedia functions that are accessed by aportable electronic device, the manufacturers of such portable electronic devices have been manufacturing devices with larger displays to respond to consumer demand. In addition, as the electronic devices are highly integrated and advanced high speed wireless communication capability, various functions that used to be performed by separate devices are now able to be performed by a single portable electronic device, for example, a mobile terminal.

The portable electronic device connects with external devices such as personal computers or electric chargers for storing large-scale files, for example, high quality moving pictures, upgrading software, or charging a battery. Recently, the portable electronic devices have been connecting with external devices via wireless communication such as Bluetooth or Near Field Communication (NFC), and the portable electronic devices have adopted a wireless charging function due to the development of a wireless power transfer technology. Currently a cloud computing environment is served by using storage space provided by service providers. Accordingly, the user can store large scale files in the portable electronic device or upgrade software of the portable electronic device without connecting via cables to external devices. However, most of the users still prefer physical connection of the portable electronic device to an electric charger (such as a USB charger) or physical connection to external devices by a separate cable for charging a battery or transmitting data to a wireless charging method due to the low efficiency of the wireless power transfer.

The portable electronic devices generally have a connection terminal for connection with the external devices. The connection terminal has connection members such as a plurality of data pins that are typically arranged according to a standard, and a connector provided in a separate cable is inserted into the connection terminal to thereby connect the portable electronic device with the external device. The connection of the connection terminal and the connector is made by an insertion structure in the form of a plug, and connection members of the plug are typically comprised of pogo pins connected under pressure.

In the connection terminal of the pogo pins, the connector of the cable fits tightly into the connection terminal for connection thereof, so the repeated fitting operation will eventually cause a failure of the pogo pins and the pins of the connector due to the stresses associated with connecting and disconnecting, which brings about an electric short circuit of the connection terminal and deterioration of the product reliability.

In addition, such a connection terminal is usually provided on the printed circuit board where a multitude of electric components are mounted, and a shield member in a double-layered structure is provided above the printed circuit board. In general, the shield member is comprised of a shield can cover that covers the printed circuit board, and a sus-plate that is stacked on the shield can cover. The purpose of the shield member is to block electromagnetic radiation created from the components of the electronic device to thereby prevent the electromagnetic interference (EMI) that disturbs operations of other electronic devices as well as the electronic device. The shield member is formed in the shape of a box having an opening at the bottom thereof to cover the electronic components.

The typical shield member of the electronic device is quite thick because it has a double-layered structure in which the sus-plate is stacked on the shield can cover. Therefore, the typical shield member requires a large space to mount the shield member in the electronic device and hinders the electronic device from being small and slim together with an increase in assembly steps and manufacturing costs.

In addition, the connection terminal of the electronic device is vulnerable to failure due to the structure by which the connection terminal fits tightly into the connector of the external device. Therefore, in order to address these recurrent problems, a different type of connection structure is required.

### SUMMARY

Accordingly, various embodiments of the present disclosure provide an electronic device that has a non-insertion connection structure and improves electrical connection with a lower failure rate than conventional insertion type connection terminals.

Various embodiments of the present disclosure provide an electronic device that has a structure by which an external connection jack is connected with a connection unit by use of a magnetic force, which facilitates electrical connection of the external connection jack and the electronic device and prevents a failure of the external connection jack and the connection unit.

Various embodiments of the present disclosure provide an electronic device adopting a shield member having a single structure, which covers electronic components in the electronic device, rather than the typical shield member of a double-layered structure. Therefore, the electronic device of the present disclosure can exhibit decreased thickness of the product and the space for mounting the shield member, so the electronic device becomes smaller and slimmer than conventional devices. Furthermore, the shielding performance and the assembly feature of the product can be enhanced with the manufacturing costs of the product reduced.

In accordance with an aspect of the present disclosure, an electronic device may include: an electronic device main body; a printed circuit board that is arranged in the electronic device main body, and that has a connection unit and a plurality of electronic components mounted thereon; and a magnetic connection device unit that is provided in the electronic device main body, and that electrically connects the connection unit with an external connection jack by a magnetic force.

In accordance with another aspect of the present disclosure, an electronic device may include: an electronic device main body that has an opening therein; a printed circuit board that has a connection unit exposed outwards through the opening, and that has a plurality of electronic components mounted thereon; a shield member that covers the electronic components; and a magnetic connection device unit that is arranged in the electronic device main body, and that electrically connects the connection unit with an external connection jack by a magnetic force.

In accordance with another aspect of the present disclosure, an electronic device adopting a connection unit may include: an electronic device main body that allows the connection unit to be exposed outwards; a printed circuit board that is arranged in the electronic device main body, and that includes a plurality of electronic components mounted thereon and the connection unit; and a shield member that covers the electronic components and the shield member.

According to various embodiments of the present disclosure, the external connection jack is electrically connected with the connection unit by means of a magnetic force in the manner of a non-insertion connection, the electrical connection of the external connection jack and the electronic device is convenient and a failure of the external connection jack and the connection unit can be prevented.

Furthermore, the thickness of the electronic device and the space for mounting the shield member can be reduced by adopting the shield member of a single structure, which covers electric components in the electronic device, rather than the typical shield member of a double-layered structure. As a result, the electronic device becomes smaller and slimmer than comparable conventional devices, and the shielding performance and the assembly feature of the product can be enhanced with the manufacturing costs of the product reduced.

### BRIEF DESCRIPTION OF THE DRAWINGS

The above and other aspects, features, and advantages of the present disclosure will become more apparent to a person of ordinary skill in the art from the following detailed description taken in conjunction with the accompanying drawings, in which:

FIG. 1 is a front perspective view of an electronic device adopting a connection unit according to various embodiments of the present disclosure;

FIG. 2 is a rear perspective view of an electronic device adopting a connection unit according to various embodiments of the present disclosure;

FIG. 3 is a perspective view of a wearable device adopting a connection unit according to various embodiments of the present disclosure;

FIG. 4 is a block diagram illustrating a network environment including an electronic device according to various embodiments of the present disclosure;

FIG. 5 is a side sectional view illustrating a configuration of an electronic device according to various embodiments of the present disclosure;

FIG. 6 is a side sectional view illustrating the operation of an electronic device according to various embodiments of the present disclosure;

FIG. 7 is an enlarged side sectional view illustrating a configuration of an electronic device according to various embodiments of the present disclosure; and

FIG. 8 is a diagram illustrating the rear side of an electronic device according to various embodiments of the present disclosure.

### DETAILED DESCRIPTION

Some of the terms used in various embodiments of the disclosure will be briefly described, and then various embodiments of the present disclosure will be described in detail.

With respect to the terms in the various embodiments of the present disclosure, the general terms which are currently and widely used are selected in consideration of functions of structural elements in the various embodiments of the present disclosure.

However, meanings of the terms may be changed according to an inventor's intention, a judicial precedent, appearance of a new technology, and the like. Further, in certain cases, terms optionally selected by the applicant may be used. In such a case, the meaning of the terms will be described in detail at the corresponding parts in the description of the present disclosure. Thus, the terms used in various embodiments of the present disclosure should be defined based on the meanings of the terms and the overall contents of the embodiments of the present disclosure instead of simple titles of the terms.

Although the terms including an ordinal number such as first, second, etc. can be used for describing various elements, the structural elements are not restricted by the terms. The terms are only used to distinguish one element from another element. For example, without departing from the scope of the present disclosure, a first structural element may be named a second structural element. Similarly, the second structural element also may be named the first structural element.

Hereinafter, an electronic device adopting a connection unit that is electrically connected with an external connection jack according to various embodiments of the present disclosure will now be described. First, the electronic devices to which various embodiments of the present disclosure are applied may include all information communication devices, multimedia devices and application devices thereof, such as mobile communication terminals operated on the basis of various communication protocols corresponding to various communication systems, video phones, e-book readers, laptop personal computers (PCs), netbook computers, personal digital assistants (PDAs), portable multimedia players (PMPs), MP3 players, mobile medical devices, cameras, wearable devices {e.g., head-mounted-devices (HMDs) such as electronic glasses, electronic clothes, electronic bracelets, electronic necklaces, electronic appcessories, electronic tattoos, or smart watches}, just to name a few non-limiting examples.

According to some embodiments, the electronic device may be a smart home appliance. For example, the smart home appliance may include at least one of a television, a digital video disk (DVD) player, an audio, a refrigerator, an air conditioner, a vacuum cleaner, an oven, a microwave oven, a washing machine, an air cleaner, a set-top box, a TV box (e.g., Samsung HomeSync™, Apple TV™, or Google TV™), a game console, an electronic dictionary, an electronic key, a camcorder, and an electronic photo frame, just to name a few non-limiting examples.

According to some embodiments, the electronic device may include at least one of various medical appliances (e.g., magnetic resonance angiography (MRA), magnetic resonance imaging (MRI), computed tomography (CT), and ultrasonic machines), navigation equipment, a global positioning system (GPS) receiver, an event data recorder (EDR), a flight data recorder (FDR), automotive infotainment device, electronic equipment for ships (e.g., ship navigation equipment and a gyrocompass), avionics, security equipment, a vehicle head unit, an industrial or home robot, an automatic teller machine (ATM) of a banking system, and a point of sales (POS) of a shop.

According to another embodiment, the electronic devices may include at least one of furniture or a part of a building/structure having a communication function, electronic boards, electronic signature receiving devices, projectors, or various measuring equipment (e.g., equipment for a water supply, an electricity, gases or radio waves).

An electronic device according to various embodiments of the present disclosure may be a combination of one or more of above described various devices. Also, an electronic device according to various embodiments of the present disclosure may be a flexible device. Also, an electronic device according to various embodiments of the present disclosure is not limited to the above described devices.

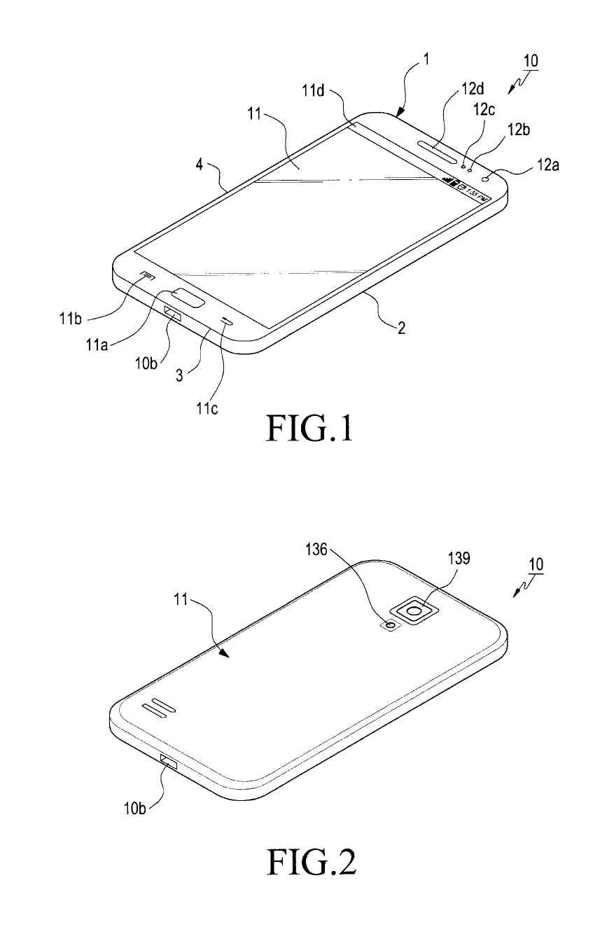

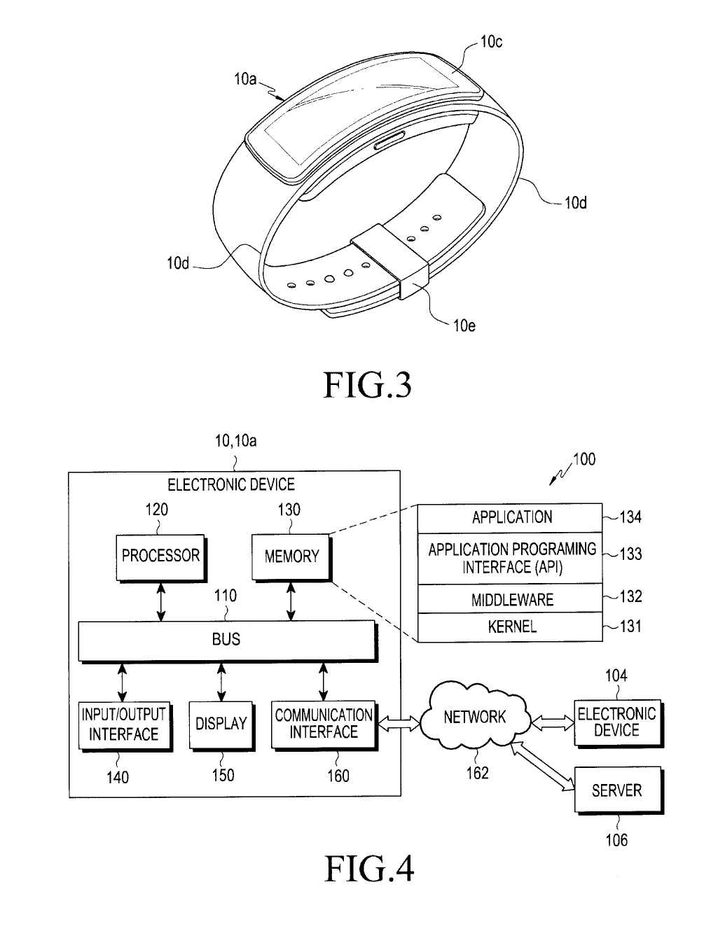

FIG. 1 is a front perspective view of an electronic device. FIG. 2 is a rear perspective view of an electronic device (e.g., electronic device 10). The electronic device 10 may be a smart phone or a wearable device 10a. FIG. 3 is a perspective view of a wearable device adopting a connection unit according to various embodiments of the present disclosure.

The configuration of the electronic device such as the smart phone and the wearable device will be described with reference to FIGS. 1, 2 and 3.

As shown in FIG. 1, a touch screen 11 may be disposed in the front surface of the electronic device 10, and may be disposed in the center of the front surface. The touch screen 11 may occupy most of the front surface of the electronic device 10. FIG. 1 shows that a main home screen image is displayed on the touch screen 11.

The main home screen image is the first screen image that is displayed on the touch screen 11 as the electronic device 10 is turned on. In addition, in the case in which the electronic device 10 has a plurality of home screen images, the main home screen image may be the first home screen image among the plurality of home screen images. In addition, icons, a main menu conversion key, time, weather, and the like to execute applications that are frequently used may be displayed in the home screen image. The main menu conversion key may allow a menu image to be displayed on the touch screen 11. In addition, a status bar 11d showing the status such as the battery percentage, the intensity of a signal, and current time may be displayed at the upper portion of the touch screen 11. A home key 11a, a menu button 11b and a back button 11c may be formed at the bottom of the touch screen 11.

Referring back to FIG. 1, the home key 11a may allow the main home screen image to be displayed on the touch screen 11. For example, when the home key 11a is touched while any home screen image other than the main home screen image, or a menu image is being displayed on the touch screen 11, the main home screen image may be displayed in the touch screen 200. In addition, when the home key 11a is touched while applications are being executed on the touch screen 11, the main home screen image may be displayed on the touch screen 11. Furthermore, the home key 11a may be used to display applications that have been recently used or a task manager on the touch screen 11. The menu button 11b may one or more provide connection menus to be used in the touch screen 11. The connection menus may include a widget addition menu, a background change menu, a search menu, an editing menu, a setup menu, and the like. The back button 11c may, for example, a display of the screen image that had been executed just before the current executed screen image or may terminate the most recently used application.

According to various embodiments of the present disclosure, the first camera 12a, an illuminance sensor 12b, or a proximity sensor 12c may be arranged at the upper portion of the front side of the electronic device 10. The second camera 139, a flash 136 or a speaker (not shown) may be provided at the rear side of the electronic device 10. In the case where a battery pack is detachable from the electronic device 10, the rear side of the electronic device 10 may serve as or may include a detachable cover for the battery.

The electronic device 10 that will be described below may be any of the wearable device 10a, the notebook, the netbook, the smart phone, the tablet PC, Galaxy Tab, or iPad, as set forth above. In the present embodiment, the wearable device 10a may be the smart watch shown in FIG. 3.

Furthermore, the electronic device 10 and the wearable device 10a can include a connection unit that is electrically connected with an external device (not shown).

As shown in FIG. 3, the wearable device 10a includes a main body 10c that performs various functions that may include some of the functions mentioned above, and a strap 10d to be strapped on the wrist, and a buckle member 10e for buckling both ends of the strap.

FIG. 4 illustrates a network environment 100 including the electronic device 10 of a smart phone or a wearable device.

Referring now to FIG. 4, the electronic device 10 may include a bus 110, a processor 120, a memory 130, an input/output interface 140, a display unit 150, and a communication interface 160. The bus 110 may be a circuit for connecting elements of the electronic device 10 with each other and transferring communication data (e.g., control messages) between the elements.

The processor 120, which comprises hardware configured for operation such as integrated circuitry may receive instructions from other elements (e.g., the memory 130, the input/output interface 140, the display unit 150, the communication interface 160, or the like) through, for example, the bus 110, then may decode the received instructions and perform calculations or data processing according to the decoded instructions.

The memory 130, which is a non-transitory machine readable medium, may store instructions or data received from the processor 120 or other elements (e.g., the input/output interface 140, the display unit 150, the communication interface 160, or the like) or created by the processor 120 or other elements. The memory 130 may include programming modules such as, for example, a kernel 131, a middleware 132, an application programming interface (API) 133, or applications 134. Each of the programming modules may be configured by machine executable code, firmware, hardware, or a combination thereof.

The kernel 131 may control or manage system resources (e.g., the bus 110, the processor 120, the memory 130, or the like) that are used in performing operations or functions implemented by other programming modules, for example the middleware 132, the API 133 or the applications 134. Further, the kernel 131 may provide an interface by which the middleware 132, the API 133 or the applications 134 may access each element of the electronic device 10 for control or management.

With continued reference to FIG. 4, the middleware 132 may play an intermediate role between the API 133 or the applications 134 and the kernel 131 to communicate with each other for transmission and reception of data. Further, in relation to requests for operation received from the applications 134, the middleware 132 may control (e.g., scheduling or load-balancing) the requests, for example, by giving priority for using system resources (e.g., the bus 110, the processor 120, the memory 130, or the like) of the electronic device 10 to at least one of the applications 134.

The API 133 is an interface by which the applications 134 controls functions provided from the kernel 131 or the middleware 132, and it may include, for example, at least one interface or function (e.g., instructions) for file control, window control, image processing, or text control.

According to various embodiments of the disclosure, the applications 134 may include a short message service (SMS)/multimedia message service (MMS) application, an e-mail application, a calendar application, an alarm application, a health care application (e.g., an application for measuring the amount of exercise or blood sugar), an environmental information application (e.g., an application for providing atmospheric pressure, humidity, or temperature), or the like, just to name a few non-limiting possibilities. Additionally or alternatively, the applications 134 may be an application related to the exchange of information between the electronic device 10 and external electronic devices (e.g., an electronic device 104). The information-exchange-related application may include, for example, a notification relay application for relaying specific information to the external electronic device, or a device management application for managing the external electronic device.

For example, the notification relay application may include a function of transferring notification information created in other applications (e.g., the SMS/MMS application, the e-mail application, the health care application, or the environmental information application) of the electronic device 10 to external electronic device (e.g., the electronic device 104). Additionally or alternatively, the notification relay application may receive notification information from, for example, an external electronic device (e.g., the electronic device 104) and provide the same to a user. The device management application may manage (e.g., install, delete, or update), for example, at least some functions {e.g., turning external electronic device (or some elements) on or off, or adjusting the brightness (or resolution) of a display} of an external electronic device (e.g., the electronic device 104) that communicates with the electronic device 10, applications executed in the external electronic device, or services (e.g., a phone call service, or a messaging service) provided in the external electronic device.

According to various embodiments of the disclosure, the applications 134 may include applications that are especially designated according to the properties (e.g., the type of electronic device) of the external electronic device (e.g., the electronic device 104). For example, if the external electronic device is an MP3 player, the applications 134 may include applications related to reproduction of music. Likewise, if the external electronic device is a mobile medical device, the applications 134 may include an application related to a health care. According to an embodiment of the disclosure, the application 134 may include at least one of applications designated in the electronic device 10 or applications received from external electronic devices (e.g., server 106 or electronic device 104).

The input/output interface 140 may include a touchscreen and/or a virtual keyboard, and may transfer instructions or data input by the user through input/output devices (e.g., sensors, keyboards, or touch screens) to the processor 120, the memory 130, or the communication interface 160 through, for example, the bus 110. For example, the input/output interface 140 may provide data on a user's touch input through a touch screen to the processor 120. For example, instructions or data received from the processor 120, the memory 130, or the communication interface module 160 occur through the bus 110 may be output through the input/output devices (e.g., speakers or displays). The input/output interface 140 may include an audio module.

The display 150 may display various pieces of information (e.g., multimedia data or text data) to the user.

The communication interface module 160 may perform communication connection between the electronic device 10 and external electronic devices (e.g., the electronic device 104 or the server 106). For example, the communication interface 160 may be connected to a network 162 through wireless communication or wired communication to thereby communicate with the external electronic device. The wireless communication may include at least one of Wi-Fi, Bluetooth (BT), Near Field Communication (NFC), a global positioning system (GPS), or cellular communication (e.g., LTE, LTE-A, CDMA, WCDMA, UMTS, WiBro, or GSM). The wired communication may include at least one of a universal serial bus (USB), a high definition multimedia interface (HDMI), recommended standard 232 (RS-232), or a plain old telephone service (POTS).

According to an embodiment of the present disclosure, the network 162 may comprise one or more telecommunication networks. The telecommunication networks may include at least one of a computer network, the Internet, the Internet of Things (IOT), or a telephone network. According to an embodiment of the disclosure, protocols (a transport layer protocol, a data link layer protocol, or a physical layer protocol) for communication between the electronic device 10 and external electronic devices may be supported by at least one of the applications 134, the API 133, the middleware 132, the kernel 131, or the communication interface 160.

According to various embodiments of the present disclosure, a controller may include a processor 120 and a memory for storing information required by the processor 120. The controller may control overall operations of the electronic device 10 as a central processing unit, and may perform an operation for supplying power to an antenna device for wireless communication as describe later.

In addition, although the electronic device according to various embodiments of the present disclosure is described to be the wearable device 10a, it is not limited thereto.

In other words, the present disclosure may be applied to any electronic device that adopts the connection unit.

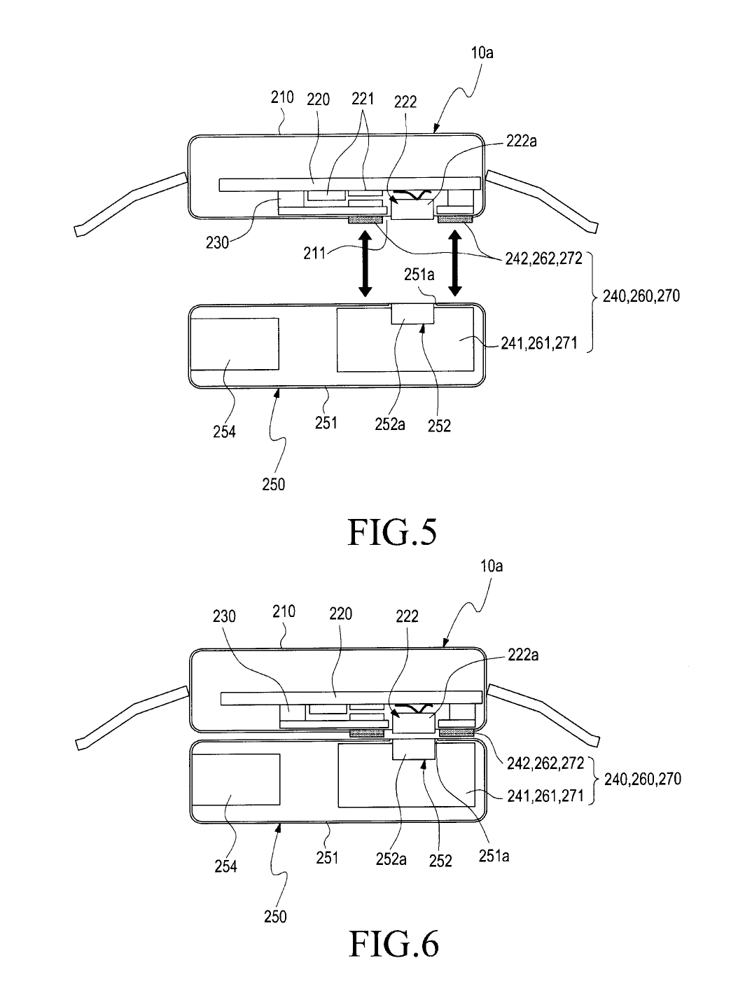

FIG. 5 is a side sectional view illustrating the configuration of an electronic device 10a that adopts a connection unit 222 according to the present disclosure, and FIG. 6 is a side sectional view illustrating the operation of an electronic device 10a according to various embodiments of the present disclosure.

Referring now to FIGS. 5 and 6, the electronic device 10a includes an electronic device main body 210, a printed circuit board 220 where a plurality of electronic components are mounted, a shield member 230, and a magnetic connection device unit 240. The electronic device main body 210 has an opening 211 through which a connection unit 222 of the printed circuit board 220 is exposed outwards. The printed circuit board 220 is arranged with the connection unit 222 that is exposed outwards through the opening 211 to be electrically connected with an external connection jack 250. The shield member 230 is positioned above the connection unit 222 and a plurality of electronic components 221, which are arranged on the printed circuit board 220, in order to shield them.

In other words, the shield member 230 can block the electromagnetic interference (EMI) created from the electronic components 221.

The magnetic connection device unit 240 is provided in the electronic device main body 210 to electrically connect the connection unit 222 and the external connection jack 250 by means of a magnetic force in the manner of non-insertion.

As described above, the present disclosure provides the magnetic connection device unit 240 that electrically connects the external connection jack with the connection unit 222 by utilizing a magnetic force in a non-insertive manner(meaning that there are not, for example, pins that penetrate receptacles. Therefore, the external connection jack 250 and the electronic device 10 can be easily connected through the use of the magnets of the connection unit, and the present disclosure prevents a premature failure of the external connection jack 250 and the connection unit 222 as comparted with conventional components that insert in a penetrated manner.

Furthermore, the present disclosure adopts the shield member 230 of a single structure, instead of the conventional shield member of a double-layered structure, for shielding the electromagnetic interference (EMI) by covering the electronic components 221 on the printed circuit board 220, so the thickness of the electronic device and the space for mounting the shield member can be reduced so that the electronic device 10a becomes smaller and slimmer than the conventional structure.

The connection unit 222 and the external connection jack 250 may have pogo pins 222a and 252a for non-insertion connection.

Moreover, the pogo pins 222a of the connection unit 222 is electrically connected with the pogo pins 252a of the external connection jack 250 in a non-inserted manner.

Here, although the pogo pins are described in the present embodiment, the claims of the present disclosure are not limited thereto. In other words, any configuration by which the connection unit 222 is connected with the external connection jack 250 in the non-inserted manner can be adopted as the connection unit.

The shield member 230 may be made of a stainless steel, for example, a “steel use stainless” sus-plate. The sus-plate may have a thickness of 0.4 T to 0.6 T. Here, the sus-plate may also have a thickness less than 0.4 T or more than 0.6 T. That is, the sus-plate may have a thickness of 0.4 T to 0.6 T as a base and 0.8 T, 0.15 T or 0.2 T in part.

The inner surface of the shield member 230 may be formed to correspond to the shapes of the electronic components 221. In other words, inner recesses may be formed on the inner surface of the shield member 230 according to the height, size and thickness of each of the electronic components 221. Accordingly, the thickness of the shield member 230 may vary with the shapes of the electronic components 221.

Now, the configuration of the magnetic connection device unit 240 of the present disclosure will be described in more detail with additional reference to FIGS. 5 and 6.

The magnetic connection device unit 240 includes a magnet 241 and a metal plate 242.

The magnet 241 creating a magnetic force is provided in the external connection jack 250 to face the metal plate 242.

The metal plate 242 is provided in the electronic device main body 210 to face the magnet 241 so that the connection unit 222 and the external connection jack 250 are electrically connected with each other by a magnetic force.

In other words, the metal plate 242 facing the magnet is provided at the lower portion of the electronic device main body 210. Therefore, as the external connection jack 250 having the magnet 241 therein approaches the metal plate 242, the magnet 241 sticks to the metal plate 242 by a magnetic force. In other words, the magnet of the external connection jack 250 attracts and sticks to the metal plate 242 of the electronic device main body 210 by a magnetic force, and at the same, the pogo pins 252a of the external connection jack 250 and the pogo pins 222a of the connection unit 222 are electrically connected.

The metal plate 242 attracts the external connection jack 250 by a magnetic force of the magnet 241 of the external connection jack 250, and at the same time, the metal plate 242 guides the pogo pins 252a of the external connection jack 250 to the pogo pins 222a of the connection unit 222 to be thereby connected with each other.

The configuration of a magnetic connection device unit 260, according to another embodiment of the present disclosure, will be described with reference to FIGS. 5 and 6.

The magnetic connection device unit 260 includes a metal plate 261 provided in the external connection jack 250 and a magnet 262 provided in the electronic device main body 210.

In other words, the metal plate 261 is provided in the external connection jack 250 to face the magnet 262. The magnet 262 faces the metal plate 261 and allows the connection unit 222 and the external connection jack 250 to be electrically connected with each other by a magnetic force.

Specifically, as the external connection jack 250 approaches the rear side of the electronic device main body 210, the magnet 262 in the electronic device main body 210 attracts and sticks to the metal plate 261 of the external connection jack 250 by a magnetic force. At this time, the pogo pins 252a of the external connection jack 250 and the pogo pins 222a of the connection unit 222 are electrically connected.

The configuration of a magnetic connection device unit 270 according to another embodiment of the present disclosure will now be described with reference to FIGS. 5 and 6.

The magnetic connection unit 270 includes the first magnet 271 provided in the external connection jack 250 and the second magnet 272 provided in the electronic device main body 210.

More particularly, the first magnet 271 is provided in the external connection jack 250 to face the second magnet 272. The second magnet 272 faces the first magnet 271 and allows the connection unit 222 and the external connection jack 250 to be electrically connected with each other by a magnetic force.

Specifically, as the external connection jack 250 approaches the rear side of the electronic device main body 210, the second magnet 272 in the electronic device main body 210 attracts and sticks to the first magnet 271 of the external connection jack 250 by a magnetic force. At this time, the pogo pins 252a of the external connection jack 250 and the pogo pins 222a of the connection unit 222 are electrically connected.

As a result of the arrangement of the structure, the first magnet 271 and the second magnet 272 attract and stick to each other by a magnetic force.

As described above, the magnet may be provided in the external connection jack 250 and the metal plate may be provided in the rear side of the electronic device main body 210. On the contrary, the metal plate may be provided in the external connection jack 250 and the magnet may be provided in the rear side of the electronic device main body 210. Alternatively, the first magnet may be provided in the external connection jack 250 and the second magnet may be provided in the rear side of the electronic device main body 210.

The magnet or the metal plate may be provided in either the external connection jack 250 or the rear side of the electronic device main body 210 to thereby connect the external connection jack 250 with the connection unit 222 by a magnetic force in the manner of non-insertion.

Now, the configuration of the external connection jack 250 according to the present disclosure will be described with reference to FIG. 5.

The external connection jack 250 includes a jack body 251, a connecting portion 252 having the pogo pins 252a therein, the magnet, and a USG terminal 254.

The jack body 251 has an opening 251a through which the pogo pins 252a are exposed outwards.

The connecting portion 252 has the pogo pins 252a that are exposed through the opening 251a, and the connecting portion 252 is provided in the jack body 251 to allow the pogo pins 252a to be electrically connected with the pogo pins 222a of the connection unit 222.

The magnet is positioned adjacent to the connecting portion 252 to attract and stick to the metal plate of the connection unit 222 by a magnetic force.

The USB terminal 254 is provided in the jack body 251 to be electrically connected with a cable terminal (not shown) that is provided in the external electronic device 10a.

The external connection jack 250 may be comprised of an electric charging gender according to the present embodiment, but the present disclosure is not limited thereto. Alternatively, the external connection jack 250 may adopt another configuration like, for example, an electric charger, rather than the electric charging gender.

Now, the assembly process of the electronic device 10a will be described in more detail.

As shown in FIGS. 6 and 8, the connection unit 222 including the pogo pins 222a is installed in the printed circuit board 220 where a plurality of electronic components 221 are mounted, and a single shield member 230 is covered above the electronic components 221. Then, the printed circuit board 220 is installed in the electronic device main body 210. The connection unit 222 of the printed circuit board 220 is exposed outwards through the opening 211 of the electronic device main body 210.

The metal plate is provided at both sides of the opening 211 of the electronic device main body 210.

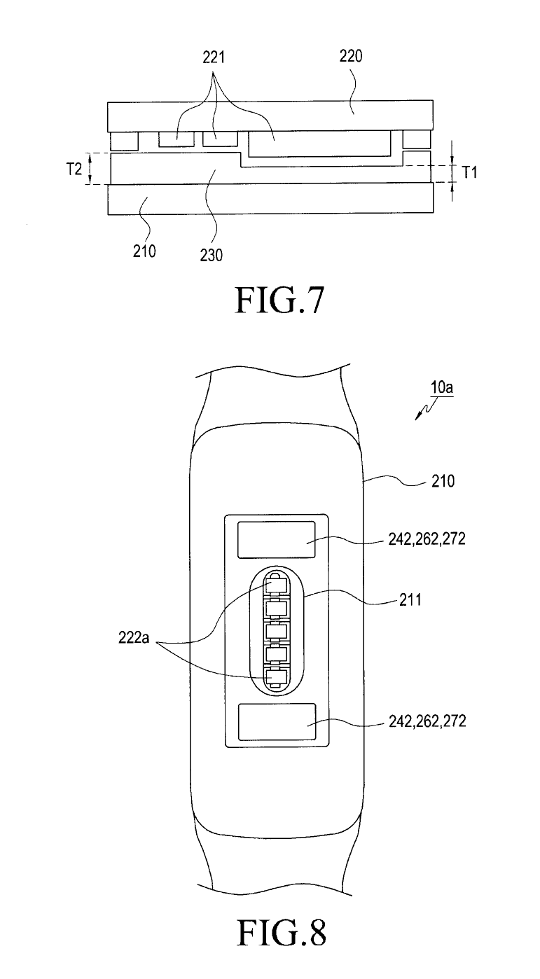

As shown in FIG. 7, the shield member 230 may have a thickness of 0.8 T for a proper tensile strength, or may be thin to provide a large area. That is, considering that it is not easy to install the shield member 230 that is thick in the electronic device 10a, the shield member 230 may have a basic thickness T2 in the range of 0.4 T to 0.6 T and a partial thickness T1 of 0.15 T.

More particularly, the thickness of the shield member 230 varies with the height, the size, and the thickness of each of the electronic components 221 of the printed circuit board 220, which are different from each other in the height, the size, and the thickness.

Accordingly, the shield member 230 and the electronic components 221 do not have a gap between them, so the electronic device 10a may become thinner and the shielding performance may be enhanced.

In this state, as the external connection jack 250 approaches the connection unit 222 of the electronic device main body 210, the magnet of the external connection jack 250 attracts and sticks to the metal plate of the connection unit 222.

At this time, the pogo pins 252a of the external connection jack 250 and the pogo pins 222a of the connection unit 222 are electrically connected.

When the USB terminal 254 of the external connection jack 250 is connected with a cable terminal (not shown) of the electric charger, the external connection jack 250 applies power to the pogo pins 222a of the connection unit 222 through the pogo pins 252a, to thereby charge a battery pack (not shown) in the electronic device main body 210.

The structure described herein does not suffer from the problems associated with the conventional connection terminal of the electronic device (not shown) fits tightly into the connector (not shown) of the external device by insertion, the repeated fitting operation causes a failure of the connection unit.

In order to cope with the above problem, in the case of charging a battery, the pogo pins 251a of the external connection jack 250 and the pogo pins 222a of the connection unit 222 may be coupled together in the manner of non-insertion by magnetic attraction between the magnet of the external connection jack 250 and the metal plate of the connection unit 222. Therefore, the charging of the electronic device 10a is convenient and a failure of the external connection jack and the connection unit due to the insertion can be prevented.

The above-described methods according to the present disclosure can be implemented in hardware, or loaded into hardware such as a processor controller, or that is stored on a non-transitory machine readable medium such as a CD ROM, a RAM, a floppy disk, a hard disk, or a magneto-optical disk or computer code downloaded over a network originally stored on a remote recording medium or a non-transitory machine readable medium and stored on a local non-transitory recording medium, so that the methods described herein are loaded into hardware such as a general purpose computer, or a special processor or in programmable or dedicated hardware, such as an ASIC or FPGA. As would be understood in the art, the computer, the processor, microprocessor controller, or the programmable hardware contain circuitry that may be integrated, and can include memory components, e.g., RAM, ROM, Flash, etc. that may store or receive computer code that when accessed and executed by the computer, processor or hardware implement the processing methods described herein. In addition, it would be recognized that when a general purpose computer accesses code for implementing the processing shown herein, via the execution of the code transforms the general purpose computer into a special purpose computer for executing the processing shown herein. In addition, an artisan understands and appreciates that a “controller”, “processor” or “microprocessor” constitute hardware in the claimed disclosure and include integrated circuitry. Under the broadest reasonable interpretation, the appended claims constitute statutory subject matter in compliance with 35 U.S.C. §101 and none of the elements constitute software per se. Nor is the disclosure a mere abstract idea.

The terms “unit” or “module” as may be used herein is to be understood as constituting or operating in conjunction with hardware such as a circuit, integrated circuit, processor or microprocessor configured for a certain desired functionality in accordance with statutory subject matter under 35 U.S.C. §101, and such terms do not constitute software perse.

While the present disclosure has been shown and described with reference to certain embodiments thereof, it will be apparent to those skilled in the art that the camera lens module according to the present disclosure is not limited to these embodiments, and various changes in form and details may be made therein without departing from the spirit and scope of the present disclosure as defined by the appended claims.

What is claimed is:

1. An electronic device comprising:
a main body;
a printed circuit board (PCB) arranged within the main body in which the PCB having a plurality of electronic components mounted thereon and further including a connection unit,
a magnetic connection device unit arranged in the connection unit in the main body that is configured for an electrical connection by a magnetic force, and
wherein the magnetic connection device unit is configured to connect electrically the connection unit with an external connection jack by a magnetic force.

2. The electronic device of claim 1, further comprising a shield member arranged above the plurality of electronic components on the PCB.

3. The electronic device of claim 1, wherein the connection unit and the external connection jack each comprise pogo pins that are in respective contact for the electrical connection between the connection unit and external connection jack.

4. An electronic device comprising:
a main body having an opening therein;
a printed circuit board (PCB) arranged within the main body and having a plurality of electronic components mounted thereon including a connection unit outwardly exposed through the opening of the main body;
a shield member covering the plurality of electronic components mounted on the PCB; and
a magnetic connection device unit arranged in the connection unit in the main body that is configured for an electrical connection by a magnetic force, and
wherein the magnetic connection device unit is configured to connect electrically the connection unit with an external connection jack by a magnetic force.

5. The electronic device of claim 4, wherein the connection unit and the external connection jack each have pogo pins that are in respective contact to form the electrical connection between the connection unit and the external connection jack.

6. The electronic device of claim 4, wherein the shield member comprises a steel use stainless (sus)-plate.

7. The electronic device of claim 4, wherein the sus-plate has a thickness of 0.4 T to 0.6 T.

8. The electronic device of claim 4, wherein the magnetic connection device unit comprises:
a magnet arranged in the external connection jack; and
a metal plate arranged in the main body to face the magnet, wherein the arrangement of the magnet and metal plate provides contact for an electrical connection between conductors of the connection unit and the external connection jack by the magnetic force.

9. The electronic device of claim 4, wherein the magnetic connection device unit comprises:
a metal plate arranged in the external connection jack; and
a magnet arranged in the main body to face the metal plate, wherein the arrangement of the metal plate and the magnet provides contact for an electrical connection between conductors of the connection unit and the external connection jack by the magnetic force.

10. The electronic device of claim 4, wherein the magnetic connection device unit comprises:
a first magnet arranged in the external connection jack; and
a second magnet arranged in the main body to face the first magnet, wherein the arrangement of the first magnet and the second magnet permits electrical connection between the connection unit and the external connection jack by the magnetic force.

11. The electronic device of claim 4, wherein the external connection jack comprises:
a jack body having an opening therein;
a connecting portion arranged in the jack body, and the connecting portion having pogo pins outwardly exposed through the opening and configured to connect electrically with the connection unit;
a magnet arranged adjacent to the connecting portion; and
a USB terminal arranged in the jack body.

12. The electronic device of claim 4, wherein the electronic device comprises one of a mobile communication terminal, a smart phone, a tablet PC, and a wearable device.

13. The electronic device of claim 12, wherein the electronic device comprises the wearable device, and further comprises one of head-mounted-devices (HMD), electronic glasses, electronic clothes, electronic bracelets, electronic necklaces, electronic appcessories, electronic tattoos, and smart watches.

14. An electronic device including a connection unit, the electronic device comprising:
a main body;
a printed circuit board (PCB) arranged within the main body, the PCB having a plurality of electronic components mounted thereon and the connection unit arranged for outward exposure from the main body; and
a shield member covering the plurality of electronic components mounted on the PCB and the connection unit.

15. The electronic device of claim 14, wherein the shield member comprises a stainless use steel (sus)-plate.

16. The electronic device of claim 15, wherein the sus-plate has a thickness of 0.4 T to 0.6 T.

17. The electronic device of claim 14, wherein an inner surface of the shield member is formed to correspond to shapes of the electronic components mounted on the PCB.

18. The electronic device of claim 14, wherein the electronic device is one of a mobile communication terminal, a smart phone, a tablet PC, and a wearable device.
